(19) United States
(12) Patent Application Publication
(10) Pub. No.: US 2007/0007505 A1
(43) Pub. Date: Jan. 11, 2007

(54) Chalcogenide PVD components

(75) Inventors: Ravi Rastogi, Liberty Lake, WA (US); Janine K. Kardokus, Liberty Lake, WA (US); Diana L. Morales, Veradale, WA (US)

Correspondence Address: WELLS ST. JOHN P.S., 601 W. FIRST AVENUE, SUITE 1300, SPOKANE, WA, 99201, US

(73) Assignee: Honeywell International Inc.

(21) Appl. No.: 11/178,202

(22) Filed: Jul. 7, 2005

(51) Int. Cl. H01L 29/02

(52) U.S. Cl. 257/2

(57) ABSTRACT

A chalcogenide PVD component includes a bonded mixture of particles of a first solid and a second solid. The first solid contains a first compound. The particle mixture may exhibit a minimum solid phase change temperature greater than a solid phase change phase temperature of an element in the first compound. The particle mixture may exhibit a maximum solid phase change temperature less than a solid phase change temperature of an element in the first compound. The first compound may be a congruently melting line compound. The bonded mixture may lack melt regions or sublimation gaps. The particle mixture may exhibit a bulk formula including three or more elements. The particle mixture may include two or more line compounds.

### TECHNICAL FIELD

The invention pertains to chalcogenide physical vapor deposition components.

### BACKGROUND OF THE INVENTION

Scaling memory technologies beyond the 45 nm node requires a significant shift outside the CMOS paradigm. Page 2 of The International Technology Roadmap For Semiconductors: 2003—Emerging Research Devices (hereinafter 2003 ITRS) states that “development of electrically accessible non-volatile memory with high speed and high density would initiate a revolution in computer architecture.” A variety of technologies are proposed in the 2003 ITRS with varying levels of risk. Phase change memory constitutes one of the lower risk technologies.

Chalcogenide alloys are a class of materials known to transition from a resistive to a conductive state through a phase change that may be activated electrically or optically. A transition from a crystalline phase state to an amorphous phase state constitutes one example of such a phase change. The transition property allows scaling to 65 to 45 nanometer line widths and smaller for next generation DRAM technology. Chalcogenide alloys exhibiting the transition property often include 2 to 6 element combinations from Groups 11-16 of the IUPAC Periodic Table (also known respectively as Groups IB, IIB, IIIA, IVA, VA, and VIA). Examples include GeSe, AgSe, GeSbTe, GeSeTe, GeSbSeTe, TeGeSbS, and AgInSbTe, as well as other alloys, wherein such listing does not indicate empirical ratios of the elements.

Technically speaking, “chalcogens” refers to all elements of Group 16, namely, oxygen, sulfur, selenium, tellurium, and polonium. Accordingly, a “chalcogenide” contains one or more of these elements. However, to date, no chalcogenide alloys have been identified that contain oxygen or polonium as the only chalcogen and exhibit the desired transition. Thus, in the context of phase change materials, the prior art sometimes uses “chalcogenide” to refer to compounds containing S, Se, and/or Te, excluding oxides that do not contain another chalcogen.

Chalcogenide compounds can be made into physical vapor deposition (PVD) targets, which in turn can be used to deposit thin films of the phase change memory material onto silicon wafers. Although several methods of depositing thin films exist, PVD, including but not limited to sputtering, will likely remain as one of the lower cost and simpler deposition methods. Apparently then, it is desirable to provide chalcogenide PVD targets.

### SUMMARY OF THE INVENTION

According to one aspect of the invention, a chalcogenide PVD component includes a rigid mass containing a bonded mixture of particles of a first solid and a second solid. The first solid contains a congruently melting first line compound and the second solid exhibits a composition different from the first solid. The particle mixture exhibits a bulk formula including at least one element selected from the group consisting of S, Se, and Te. By way of example, the bulk formula may include three or more elements selected from the group consisting of metals and semimetals in Groups 11-16. The second solid may include a congruently melting second line compound different from the first line compound. The particle mixture may exhibit a minimum solid phase change temperature that is greater than a solid phase change phase temperature of one or more element in the first line compound. The particle mixture may exhibit a maximum solid phase change temperature that is less than a solid phase change temperature of one or more element in the first line compound.

According to another aspect of the invention, a chalcogenide PVD component includes a rigid mass containing a bonded mixture of particles of a first solid and a second solid. The first solid contains a first compound and the second solid exhibits a composition different from the first solid. The particle mixture exhibits a bulk formula including at least one element selected from the group consisting of S, Se, and Te. The particle mixture also exhibits a minimum solid phase change temperature that is greater than a solid phase change temperature of one or more elements in the first compound.

According to yet another aspect of the invention, a chalcogenide PVD component includes a sputtering target blank containing a solid phase bonded, homogeneous mixture of particles of a first solid, a second solid, and one or more additional solid. The particle mixture lacks melt regions or sublimation gaps. The first, second, and additional solids respectively consist of different, congruently melting first, second, and one or more additional line compounds. The particle mixture exhibits a bulk formula including three or more elements, at least one of which is selected from the group consisting of S, Se, and Te. The particle mixture exhibits a minimum solid phase change temperature that is greater than a solid phase change temperature of one or more elements in the first, second, or additional line compound.

### BRIEF DESCRIPTION OF THE DRAWINGS

Preferred embodiments of the invention are described below with reference to the following accompanying drawings.

FIG. 1 is a sectional view taken along line 1-1 in FIG. 2 of a sputtering target/backing plate construction in accordance with an aspect of the invention. The construction corresponds to a large ENDURA™ configuration.

FIG. 2 is a top view of the sputtering target/backing plate construction shown in FIG. 1.

FIG. 3 shows a flow chart depicting a conventional PVD component forming method.

FIG. 4 shows a flow chart depicting a method of making a PVD component according to an aspect of the invention.

### DETAILED DESCRIPTION OF THE PREFERRED EMBODIMENTS

In most PVD processes, the only significant deposition occurs from a target containing the desired material. However, in some PVD processes non-target components of the deposition apparatus may significantly contribute to deposition and thus contain the same material as the target. In the context of the present document, a PVD “component” is defined to include targets as well as other non-target components. Similarly, “PVD” is defined to include sputtering as well as other physical vapor deposition methods known to those of ordinary skill.

Phase change memory research often involves identification of particular compositional formulations with two or more alloying elements. Unfortunately, composition control presents a difficulty in forming chalcogenide alloy PVD components. Generally, such alloys exhibit a wide temperature and/or pressure phase change region between solid and liquid (melting) or solid and gas (sublimating) phases. Processing may include strongly exothermic reactions between elements, for example, between Ag/Se and between Ge/Se. Processing may include solid to liquid and/or to gas phase changes. The reactions and/or phase changes can segregate elements in the alloys and producing a solid containing a range of compositions.

Conventional attempts at controlling segregation include very rapid heating and cooling in a quartz ampoule to control outgassing of low melting elements. Such attempts complicate processing and have only found success in forming some binary and some ternary compounds. Understandably, complex fabrication methods might not be cost effective and/or compatible with existing semiconductor fabrication process flows and control systems, especially those involving four or more chalcogenide alloying elements.

Other fabrication technologies that might be explored include liquid phase epitaxy or chemical vapor deposition, but they may be prohibitively difficult to deposit chalcogenide alloys given the need for complex compositional control and the likely poor cost effectiveness. Atomic layer deposition presents another possibility, but stable, predictable precursors do not appear readily available for all elements of interest given the relative immaturity of such technology.

PVD of chalcogenide alloy films presents one of the few commercially practicable methods of forming a chalcogenide alloy composition. Even so, PVD component fabrication presents it own difficulties. Areas of concern include segregation between solid and liquid phase transitions, the hazardous nature of some elemental constituents of chalcogenide alloys, and the risk of contaminating conventional PVD component blanks fabricated in the same processing equipment as chalcogenide alloy component blanks. In addition, chalcogenide alloys tend to exhibit brittleness similar to gallium arsenide, creating difficulties with breakage during bonding, finishing, and general handling of the blank and component.

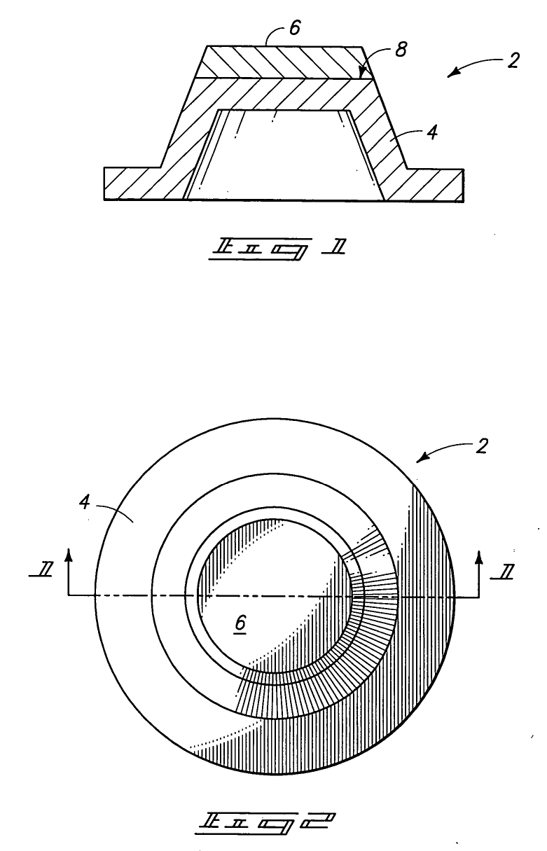

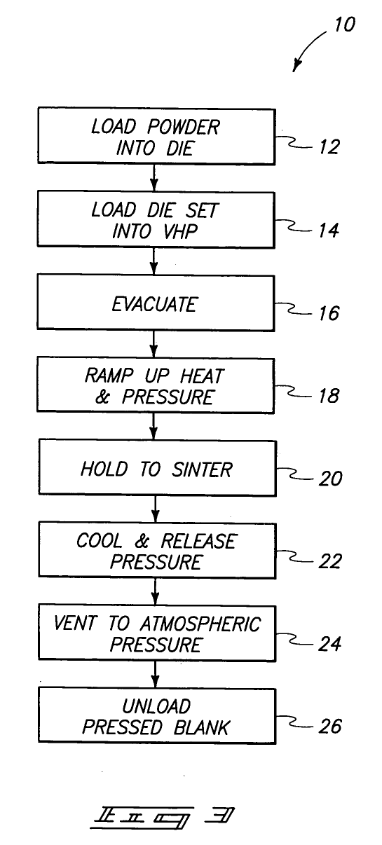

An exemplary PVD assembly having a backing plate and target is shown in FIGS. 1 and 2 as assembly 2. Assembly 2 includes a backing plate 4 bonded to a target 6. Backing plate 4 and target 6 join at an interface 8, which can include, for example, a diffusion bond between the backing plate and target. Backing plate 4 and target 6 can include any of numerous configurations, with the shown configuration being exemplary. Backing plate 4 and target 6 can include, for example, an ENDURA™ configuration, and accordingly can have a round outer periphery. FIG. 2 shows assembly 2 in a top view and illustrates the exemplary round outer periphery configuration.

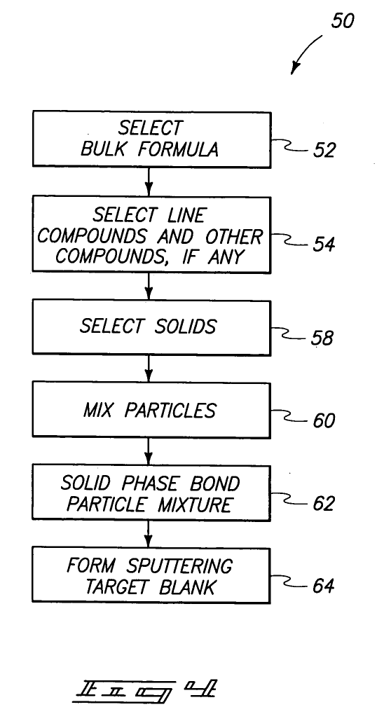

Vacuum hot pressing (VHP) represents a specific method conventionally used for producing a chalcogenide PVD component. Method 10 shown in FIG. 3 exemplifies possible steps in a VHP process. Step 12 involves loading a pre-made powder into a die set. The powder exhibits a bulk composition matching the desired composition of the component blank. In step 14, the die set may be loaded into a VHP apparatus. Following evacuation in step 16, heat and pressure ramping occurs during step 18. Sintering during step 20 occurs at a temperature below the onset of melting, but at a high enough temperature and pressure to produce a solid mass of the powder particles. Cooling and releasing pressure in step 22 is followed by venting the VHP apparatus to atmospheric pressure in step 24. The pressed blank is unloaded in step 26.

Although a relatively simple method, observation indicates that VHP presents some difficulties. VHP apparatuses are typically designed for high temperature and pressure processing of refractory metal powder materials. A high risk of melting exists in such systems where the chalcogenide composition includes low melting elemental constituents, such as selenium or sulfur. Melting during VHP may release hazardous vapors from the chalcogenide composition, contaminate and/or damage the VHP apparatus, and ruin the end product. Blanks with compositions that melt during VHP may stick to the die set and crack upon removal of the processed blank. Also, melted material that leaks past split sleeves of the die set can solidify during cooling, creating a wedge effect. The resulting high shear stress on the die set may cause catastrophic failure.

A chalcogenide PVD component according to the aspects of the invention described herein minimizes the indicated problems. In addition to a VHP, a hot isostatic press (HIP), cold isostatic press (CIP), etc. constitute acceptable consolidation apparatuses. Cold isostatic pressing may be followed by a sintering anneal. Typically, HIP or VHP processing includes sintering. Sintering, followed by cooling and releasing pressure, completes consolidation of the particle mixture. The removed blank may meet specifications for use as a PVD component or further processing known to those of ordinary skill may bring the blank into conformity with component specifications.

A chalcogenide PVD component forming method includes mixing particles of a first solid with particles of a second solid and forming a rigid mass containing the particle mixture in bonded form. The first solid contains a congruently melting first line compound. The second solid exhibits a composition different from the first solid. The particle mixture exhibits a bulk formula including at least one element selected from the group consisting of S, Se, and Te. By way of example, the bulk formula may include three or more elements selected from the group consisting of metals and semimetals in Groups 11-16 of the IUPAC Periodic Table. Many of the presently identified advantageous chalcogenides consist of metals and semimetals in Groups 13-16. Semimetals in Groups 11-16 include boron, silicon, arsenic, selenium, and tellurium. Metals in Groups 11-16 include copper, silver, gold, zinc, cadmium, mercury, aluminum, gallium, indium, thallium, germanium, tin, lead, antimony, bismuth, and polonium.

The second solid may include a congruently melting second line compound different from the first line compound. The particle mixture may be a powder. The powder may exhibit a particle size range of from 1 to 10,000 μm or, more advantageously, from 15 to 200 μm. Although a minimum and a maximum are listed for the above described ranges, it should be understood that more narrow included ranges may also be desirable and may be distinguishable from prior art. The bulk formula may include an element that is not in Groups 11-16. However, the bulk formula may consist of elements selected from Groups 11-16. Some exemplary bulk formulas include: GeSbTe, GeSeTe, GeSbSeTe, TeGeSbS, AginSbTe, and SbGeSeSTe, as well as others, wherein such listing does not indicate empirical ratios of the elements. Understandably, certain elements in the bulk formulas may be provided in greater or lesser abundance compared to relative amounts of the other elements depending on the intended use of the PVD component. The rigid mass may exhibit a density of at least 95% of theoretical density or, more advantageously, at least 99%.

The particle mixture may contain two or more of the following line compounds: GeSe, GeSe₂, GeS, GeS₂, GeTe, Sb₂Se₃, Sb₂S₃, and Sb₂Te₃. For example the particle mixture may contain three of the listed line compounds. In the context the present document, “line compound” refers to particular compositions appearing in solid-liquid phase diagrams as congruently melting compositions. Such compounds are also referred to in the art as “intermediate compounds.” For congruently melting line compounds, the liquid formed upon melting has the same composition as the solid from which it was formed. Other solid compositions appearing in a phase diagram typically melt incongruently so that the liquid formed upon melting has a composition different than the solid from which it was formed.

When forming a chalcogenide PVD component, a particle mixture containing at least one element selected from the group consisting of S, Se, and Te may contain low and high melting elements creating a range of melting points so large that processing becomes difficult. As the number of different elements increases to three or more, especially to five or more, the difficulty associated with mixed low and high melting elements may similarly increase. In the discussion above, processing the particle mixture to form a rigid mass suitable to be used as a PVD component can melt the low melting elements. The melted elements can produce strong exothermic reactions, outgas, segregate into melt regions exhibiting a composition different from regions of particle mixture that did not melt, sublimate to produce gaps in the particle mixture, or create other manufacturing difficulties. Such non-uniformities in PVD components may produce poor compositional control in the deposited thin films. The presence or absence of melt regions and/or sublimation gaps might be verifiable by comparing local composition variations to bulk composition and/or by visual inspection techniques.

As stated above, the first solid contains a congruently melting first line compound. The particle mixture may exhibit a minimum solid phase change temperature that is greater than a solid phase change phase temperature of one or more element in the first line compound. The solid phase change temperature may be a melting point or a sublimation point. By providing a low melting element in the first line compound instead of as an elemental constituent, the minimum solid phase change temperature of the particle mixture may increase so that it is greater than the solid phase change temperature of the lowest melting or sublimating element. A similar effect may be obtained by including a low melting element in an incongruently melting compound which nevertheless exhibits a higher solid phase change temperature than the low melting element. By providing the low melting element in a pre-reacted state, less risk exists of manufacturing difficulties.

Forming the rigid mass containing the particle mixture might include subjecting the mixture to a temperature close to the melting point of the first line compound. However, even if the first line compound melts, the liquid-produced will exhibit the same composition as the solid from which is was formed and will be pre-reacted to avoid reaction with other compounds or elemental constituents. The congruently melting line compound thus minimizes segregation and exothermic reactions in the PVD component.

The temperature selected for forming the rigid mass might be partially determined by the maximum solid phase change temperature of the particle mixture. Generally speaking, the greatest densification occurs at sintering temperatures as close a possible to a maximum solid phase change temperature of a particle mixture. Accordingly, the particle mixture may exhibit a maximum solid phase change temperature that is less than a solid phase change temperature of one or more element in the first line compound. By providing a high melting element in the first line compound instead of in an elemental constituent, the maximum solid phase change temperature of the particle mixture may decrease so that it is less than the solid phase change temperature of the highest melting or sublimating element. A similar effect may be obtained by including a high melting element in an incongruently melting compound which nevertheless exhibits a lower solid phase change temperature than the high melting element.

Decreasing the maximum solid phase change temperature may allow lowering of a temperature selected for forming the rigid mass. At lower process temperatures, less risk may exist for melting or sublimating other constituents of a particle mixture. Accordingly, aspects of the invention provide for narrowing the solid phase change temperature range of a particle mixture from the low melting side, the high melting side, or both.

In the example above of SbGeSeSTe, Table 1 shows that Se and S exhibit respective melting points of 217° C. and 115° C. If S is instead provided as a line compound with S₃Sb₂, and Se is provided as a line compound with GeSe and Sb₂Se₃, then the minimum melting point increases to that of Te, 449.5° C. Table 2 shows the melting points of the line compounds. Thus, significant advantage results from using compounds containing low melting elements where the compound exhibits a higher solid phase change temperature.

Table 1 shows that Ge exhibits a melting point of 937° C. If Ge is provided as a line compound with GeSe, then the maximum melting point decreases to that of GeSe, 660° C. Table 2 shows the melting points of the line compounds. Thus, significant advantage also results from using compounds containing high melting elements where the compound exhibits a lower solid phase change temperature.

Especially significant advantage results when substituted compounds are line compounds due to the congruent melting property. Particle consolidation methods, for example HIP, CIP coupled with sintering, or VHP, may operate at close to the minimum solid phase change temperature of a particle mixture to maximize densification during the consolidation process. In the event that melting of a line compound occurs, minimal segregation problems result, if any. More significant segregation problems may result if compounds melt incongruently.

By way of example, the particle mixture may be a powder. The powder may exhibit a particle size range of from 1 to 10,000 μm or, more advantageously, from 15 to 200 μm. The rigid mass may exhibit a density of at least 95% of theoretical density or, more advantageously, at least 99%. Given the stability of the particle mixture described above containing a first solid with a congruently melting first line compound, a wider variety of consolidation techniques might be suitable for forming the rigid mass containing the particle mixture in bonded form. The stability reduces the negative impact of melting. However, a desire nevertheless exists to form the rigid mass by solid phase bonding the particle mixture without creating melt regions or sublimation gaps.

With such a result as the goal, consolidation techniques may be selected that maximize densification of the particle mixture into a rigid mass by drawing nearer to the point of creating melt regions since the negative effect of unintentionally melting is less. Potential negative effects become less likely as the number of elements provided in elemental constituents decreases and the number of elements provided in line compounds increases. In the context of the present discussion, stability is improved by providing a line compound as the lowest melting constituent. Stability is further improved if any elemental constituents or incongruently melting compounds have a solid phase change temperature that is significantly greater than the minimum solid phase change temperature of the particle mixture. In this manner, approaching the minimum solid phase change temperature only risks melting or sublimating a line compound without risking melting or sublimating an elemental constituent or incongruently melting constituent. HIP, CIP, or VHP all constitute possible solid phase bonding techniques.

In a further aspect of the invention, a chalcogenide PVD component forming method includes mixing particles of a first solid with particles of a second solid and forming a rigid mass containing the particle mixture in bonded form. The first solid contains a first compound, the second solid exhibits a composition different from the first solid, and the particle mixture exhibits a bulk formula including at least one element selected from the group consisting of S, Se, and Te. The particle mixtures exhibits a minimum solid phase change temperature that is greater than a solid phase change temperature of one or more element in the first compound. Accordingly, by including a low melting element in the first compound, the minimum solid phase change temperature may be raised to exceed the solid phase change temperature of the low melting element.

The first compound may be a line compound or an incongruently melting compound. While use of line compounds offers more advantages in comparison to incongruently melting compounds, the present aspect of the invention may still be advantageous even in the circumstance where no line compound is included in the particle mixture. For example, if the minimum solid phase change temperature is determined by an elemental constituent rather than by the incongruently melting compound. Thus, with the solid phase change temperature of the incongruently melting compound greater than the minimum solid phase change temperature, the risk is still reduced of producing melt regions or sublimation gaps.

In a still further aspect of the invention, a chalcogenide PVD component forming method includes selecting a particle mixture exhibiting a bulk formula including three or more elements, at least one of which is selected from the group consisting of S, Se, and Te. The method includes selecting different, congruently melting first, second, and one or more additional line compounds to be contained in the particle mixture and providing particles of a first solid, a second solid, and one or more additional solid respectively consisting of the first, second, and one or more additional line compounds. The method includes homogeneously mixing particles of at least the first solid, the second solid, and the additional solid. The mixing uses proportions which yield the selected bulk formula and the particle mixture exhibits a minimum solid phase change temperature that is greater than a solid phase change temperature of one or more element in the first, second, or additional line compound. The particle mixture is solid phase bonded without creating melt regions or sublimation gaps. The method includes forming a sputtering target blank containing the bonded particle mixture.

By way of example, the bulk formula may include five or more elements selected from the group consisting of metals and semimetals in Groups 11-16. The particle mixture may further include particles of another solid which does not contain a line compound.

Method 50 shown in FIG. 4 provides some exemplary features of the aspects of the invention. The desired bulk formula is selected in step 52 and, in step 54 appropriate line compounds, incongruently melting compounds, and/or elemental constituents are identified. A study of solid phase change temperatures of the compounds and elements may be used to reveal low and/or high melting elements and possible compounds in which the elements may be included to raise the minimum and/or lower the maximum solid phase change temperature. Proportions of the compounds and elemental constituents, if any, may be determined to achieve the bulk formula selected in step 52. The discussion of Table 1-3 below provides more detail in this regard.

Once the compounds and elemental constituents, if any, along with their respective proportions are determined, selection of solids containing the desired materials occurs in step 58. The selected solids might be commercially available or method 50 could include preparing them according to known methods. If solids are used that consist only of individual compounds and elemental constituents, then the previous determination of mass proportions for such compounds and elemental constituents will match the mass proportions for the selected solids. However, a desire may exist to use solids that contain multiple compounds and/or elemental constituents. In such case, proportions of the solids which yield the selected bulk formula may be determined and may differ from the proportions determined for the individual compounds and elemental constituents.

Particles of the selected solids may be mixed in step 60. Typically, a desire exists for a PVD component to provide uniform deposition of a film exhibiting the selected bulk formula. Accordingly, homogeneous mixing of particles facilitates forming a homogeneous PVD component and meeting deposition specifications for the thin film. Powder blenders and other apparatus known to those of ordinary skill may be used to homogeneously mix particles. The particles may be powders and exhibit the particle size ranges discussed herein. Solid phase bonding techniques such as described herein may be used in step 62 to bond the particle mixture.

Depending upon the selection of line compounds, incongruently melting compounds, and elemental constituents in step 54 and process conditions, the bonded particle mixture may or may not exhibit melt regions and/or sublimation gaps. In the most advantageous circumstance, solid phase bonding occurs without creating melt regions or sublimation gaps. In less advantageous circumstances that nevertheless address problems described for the prior art, small melt regions or sublimation gaps may exist but not detract significantly from homogeneity of the bonded particle mixture depending upon the particular melted or sublimated compound or elemental constituents. To the extent that the solid phase bonding technique does not produce a sputtering target blank or other PVD component within specifications, further processing may occur in step 64 to bring the desired component within specifications.

Given the methods described herein for forming chalcogenide PVD components, it follows that aspects of the invention also include chalcogenide PVD components themselves. In one aspect of the invention, a chalcogenide PVD component includes a rigid mass containing a bonded mixture of particles of a first solid and a second solid. The first solid contains a congruently melting first line compound and the second solid exhibits a composition different from the first solid. The particle mixture exhibits a bulk formula including at least one element selected from the group consisting of S, Se, and Te. By way of example, the chalcogenide PVD components described herein may exhibit the formulas, compositions, properties, features, etc. discussed herein in relation to other aspects of the invention.

In another aspect of the invention, a chalcogenide PVD component includes a rigid mass containing a bonded mixture of particles of a first solid and a second solid. The first solid contains a first compound and the second solid exhibits a composition different from the first solid. The particle mixture exhibits a bulk formula including at least one element selected from the group consisting of S, Se, and Te. The particle mixture also exhibits a minimum solid phase change temperature that is greater than a solid phase change temperature of one or more elements in the first compound.

In a further aspect of the invention, a chalcogenide PVD component includes a sputtering target blank containing a solid phase bonded, homogeneous mixture of particles of a first solid, a second solid, and one or more additional solid. The particle mixture lacks melt regions or sublimation gaps. The first, second, and additional solids respectively consist of different, congruently melting first, second, and one or more additional line compounds. The particle mixture exhibits a bulk formula including three or more elements, at least one of which is selected from the group consisting of S, Se, and Te. The particle mixture exhibits a minimum solid phase change temperature that is greater than a solid phase change temperature of one or more elements in the first, second, or additional line compound.

Table 1 shows a hypothetical example of a five-element formula for a chalcogenide PVD component. Using the desired atomic % (at. %) and the atomic weight (at. wt.) of each element, the required mass of each element may be calculated and is shown in Table 1. Table 1 also shows that, aside from selenium and sulfur, the range of solid phase change temperatures extends from 450° C. to 937° C. With selenium and sulfur melting at 217 and 115° C., respectively, adequate solid phase bonding of particles consisting of elemental constituents listed in Table 1 may be difficult without producing significant manufacturing problems such as segregation, exothermic reactions, etc. Table 2 lists known binary line compounds for elements listed in Table 1. Additional pertinent line compounds may exist. Noticeably, the line compounds listed all exhibit melting points much higher than the selenium and sulfur melting points. Also, the line compounds listed all exhibit melting points much lower than the germanium melting point.

TABLE 1

| Element | At. % | At. Wt. | Gram/Mol | MP (° C.) |
|---|---|---|---|---|
| Sb | 15 | 121.76 | 18.26 | 630.74 |
| Ge | 15 | 72.64 | 10.90 | 937.4 |
| Se | 30 | 78.96 | 23.69 | 217 |
| S | 20 | 32.065 | 6.41 | 115.21 |
| Te | 20 | 127.6 | 25.52 | 449.5 |
| Total | 100 | | 84.78 | |

TABLE 2

| Compounds | At. % A element | At. % B element | MP (° C.) |
|---|---|---|---|
| GeSe | 50 | 50 | 660 |
| GeSe₂ | 33.3 | 66.7 | 742 |
| GeS | 50 | 50 | 665 |
| GeS₂ | 33.3 | 66.7 | 840 |
| GeTe | 50 | 50 | 724 |
| S₃Sb₂ | 60 | 40 | 550 |
| Sb₂Se₃ | 40 | 60 | 590 |
| Sb₂Te₃ | 40 | 60 | 618 |

As may be appreciated, the desired bulk formula may be obtained by selecting certain line compounds in appropriate mass proportions. Depending upon the selections, the line compounds may raise the minimum solid phase change temperature and/or lower the maximum solid phase change temperature. Table 3 lists three exemplary line compounds and one continuous solid solution (SeTe). Table 3 lists the mass of individual elements contributed from the total mass of each of the three compounds and one solid solution. The total contributed mass of each element matches the required mass listed in Table 1 to produce the desired at. % of each element.

TABLE 3

| | | | | Mass (gm/mol) | | | | | |
|---|---|---|---|---|---|---|---|---|---|
| Cmpnd | At. % A | At. % B | MP ° C. | S | Se | Sb | Ge | Te | Total |
| GeSe | 50 | 50 | 660 | | 11.84 | | 10.90 | | 22.74 |
| Sb₂Se₃ | 40 | 60 | 690 | | 1.97 | 2.03 | | | 4.00 |
| S₃Sb₂ | 60 | 40 | 550 | 6.41 | | 16.23 | | | 22.65 |
| SeTe* | 38.5 | 61.5 | 270 | | 9.87 | | | 25.52 | 35.39 |
| | | | Total | 6.41 | 23.69 | 18.26 | 10.90 | 25.52 | 84.78 |

*Not a line compound

Table 3 lists a SeTe continuous solid solution containing 38.5 at. % Se and 61.5 at. % Te. A 50 at. %/50 at. % SeTe solid solution exhibits a melting point of about 270° C. and the SeTe solid solution in Table 3 contains more Te which exhibits a melting point of 449.5° C. Thus, it is expected that the melting point of the SeTe in Table 3 will be higher. Accordingly, the solid phase change temperature range for the compounds in Table 3 is less than 420° C. compared to 822° C. for the elements listed in Table 1. Solid phase bonding of a particle mixture containing the compounds listed in Table 3 may thus proceed under more advantageous process conditions and achieve more advantageous properties in comparison to conventional chalcogenide PVD component forming methods.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

We claim:

1. A chalcogenide PVD component comprising:
a rigid mass containing a bonded mixture of particles of a first solid and a second solid;
the first solid comprising a congruently melting first line compound and the second solid exhibiting a composition different from the first solid; and
the particle mixture exhibiting a bulk formula including at least one element selected from the group consisting of S, Se, and Te.

2. The component of claim 1 wherein the bulk formula includes three or more elements selected from the group consisting of metals and semimetals in Groups 11-16.

3. The component of claim 1 wherein the particle mixture exhibits one of the following bulk formulas, which do not indicate empirical ratios: GeSbTe, GeSeTe, GeSbSeTe, TeGeSbS, AginSbTe, or SbGeSeSTe.

4. The component of claim 1 wherein the particle mixture contains two or more of the following line compounds: GeSe, GeSe₂, GeS, GeS₂, GeTe, Sb₂Se₃, Sb₂S₃, and Sb₂Te₃.

5. The component of claim 1 wherein the second solid comprises a congruently melting second line compound different from the first line compound.

6. The component of claim 1 wherein the particle mixture exhibits a minimum solid phase change temperature that is greater than a solid phase change temperature of one or more element in the first line compound.

7. The component of claim 1 wherein the particle mixture exhibits a maximum solid phase change temperature that is less than a solid phase change temperature of one or more element in the first line compound.

8. The component of claim 1 wherein the mass is a sputtering target blank and the component further comprises a backing plate bonded to the blank.

9. The component of claim 1 wherein the mass consists of a mixture of solid phase bonded particles without melt regions or sublimation gaps.

10. A chalcogenide PVD component comprising:
a rigid mass containing a bonded mixture of particles of a first solid and a second solid;
the first solid comprising a first compound and the second solid exhibiting a composition different from the first solid;
the particle mixture exhibiting a bulk formula including at least one element selected from the group consisting of S, Se, and Te; and
the particle mixture exhibiting a minimum solid phase change temperature that is greater than a solid phase change temperature of one or more element in the first compound.

11. The component of claim 10 wherein the bulk formula includes three or more elements selected from the group consisting of metals and semimetals in Groups 11-16.

12. The component of claim 10 wherein the particle mixture exhibits one of the following bulk formulas, which do not indicate empirical ratios: GeSbTe, GeSeTe, GeSbSeTe, TeGeSbS, AgInSbTe, or SbGeSeSTe.

13. The component of claim 10 wherein the particle mixture contains two or more of the following line compounds: GeSe, GeSe₂, GeS, GeS₂, GeTe, Sb₂Se₃, Sb₂S₃, and Sb₂Te₃.

14. The component of claim 10 wherein the second solid comprises a second compound and the particle mixture exhibits a maximum solid phase change temperature that is less than a solid phase change temperature of one or more element in the second compound.

15. The component of claim 10 wherein the mass is a sputtering target blank and the component further comprises a backing plate bonded to the blank.

16. The component of claim 10 wherein the mass consists of a mixture of solid phase bonded particles without melt regions or sublimation gaps.

17. A chalcogenide PVD component comprising:
a sputtering target blank containing a solid phase bonded, homogeneous mixture of particles of a first solid, a second solid, and one or more additional solid, the particle mixture lacking melt regions or sublimation gaps;
the first, second, and additional solids respectively consisting of different, congruently melting first, second, and one or more additional line compounds;
the particle mixture exhibiting a bulk formula including three or more elements, at least one of which is selected from the group consisting of S, Se, and Te; and
the particle mixture exhibiting a minimum solid phase change temperature that is greater than a solid phase change temperature of one or more element in the first, second, or additional line compound.

18. The component of claim 17 wherein the bulk formula includes five or more elements selected from the group consisting of metals and semimetals in Groups 11-16.

19. The component of claim 17 wherein the particle mixture further comprises particles of another solid which does not contain a line compound.

20. The component of claim 17 wherein the particle mixture exhibits a maximum solid phase change temperature that is less than a solid phase change temperature of one or more element in the first, second, or additional line compound.
